(19) United States
(12) Patent Application Publication
(10) Pub. No.: US 2022/0399376 A1
(43) Pub. Date: Dec. 15, 2022

(54) ARRAY SUBSTRATE, METHOD FOR MANUFACTURING SAME, AND DISPLAY PANEL

(71) Applicant: Shenzhen China Star Optoelectronics Semiconductor Display Technology Co., Ltd., Shenzhen, Guangdong (CN)

(72) Inventors: Gongtan LI, Shenzhen, Guangdong (CN); Shan LI, Shenzhen, Guangdong (CN); Hyunsik SEO, Shenzhen, Guangdong (CN)

(21) Appl. No.: 17/422,195

(22) PCT Filed: Jun. 22, 2021
(86) PCT No.: PCT/CN2021/101587

§ 371 Date: Jul. 11, 2021

(30) Foreign Application Priority Data
Jun. 11, 2021 (CN) 202110650642.6

(51) Int. Cl. H01L 27/12; G02F 1/1362

(52) U.S. Cl. CPC H01L 27/1225; H01L 27/127; G02F 1/136209

(57) ABSTRACT

An array substrate, a method for manufacturing the same, and a display panel are provided. The array substrate includes a substrate, a first metal layer, a buffer layer, and a semiconductor layer. The first metal layer includes a source electrode, a drain electrode, and a light shielding portion. The semiconductor layer is electrically connected to the source electrode through a first via hole penetrating the buffer layer, and is electrically connected to the drain electrode through a second via hole penetrating the buffer layer. The source electrode, the drain electrode, and the light shielding portion can be formed by a same yellow light process, thereby reducing a number of photomasks and a number of process steps.

### FIELD OF INVENTION

The present disclosure relates to the technical field of display, and particularly to an array substrate, a method for manufacturing the same, and a display panel.

### BACKGROUND

Oxide thin film transistor technology is considered to be a promising replacement for amorphous silicon thin film transistor technology and has become a mainstream technology for the next generation of display driver backplanes. Compared with amorphous silicon thin film transistor technology, oxide thin film transistors have characteristics of higher mobility (μ>10 cm²/Vs), good uniformity in large areas, and lower production costs. However, stability of oxide thin film transistors still has some problems. Compared with an oxide thin film transistor with a back channel etch (BCE) structure, an oxide thin film transistor with a top gate structure has better stability. However, an oxide thin film transistor with a top gate structure requires a greater number of process steps and a greater number of photomasks, resulting in higher costs.

Accordingly, it is necessary to provide a new array substrate, a method for manufacturing the same, and a display panel to solve the above technical problems.

### SUMMARY OF DISCLOSURE

The present disclosure provides an array substrate, a method for manufacturing the same, and a display panel, so as to solve the technical problem of higher cost due to a greater number of process steps and a greater number of photomasks required for manufacture of current array substrates.

In order to solve the above technical problem, the present disclosure provides the following technical solutions.

The present disclosure provides an array substrate comprising:

a substrate;

a first metal layer disposed on the substrate and comprising a source electrode, a drain electrode, and a light shielding portion;

a buffer layer covering the first metal layer and provided with a first via hole penetrating the buffer layer and corresponding to the source electrode and a second via hole penetrating the buffer layer and corresponding to the drain electrode; and

a semiconductor layer disposed on the buffer layer, electrically connected to the source electrode through the first via hole, and electrically connected to the drain electrode through the second via hole.

In an embodiment, the source electrode and the drain electrode are disposed on and spaced apart from opposite sides of the light shielding portion.

In an embodiment, the source electrode and the drain electrode are disposed on opposite sides of the light shielding portion. One side of the light shielding portion is connected to the source electrode, and the other side of the light shielding portion is spaced apart from the drain electrode. Alternatively, one side of the light shielding portion is connected to the drain electrode, and the other side of the light shielding portion is spaced apart from the source electrode.

In an embodiment, the array substrate further comprises:

a gate insulating layer disposed on the semiconductor layer;

a second metal layer disposed on the gate insulating layer and comprising a gate electrode;

an interlayer dielectric layer covering the buffer layer, the semiconductor layer, the gate insulating layer, and the gate electrode; and

a transparent electrode disposed on the interlayer dielectric layer and electrically connected to the source electrode.

In an embodiment, an orthographic projection of the gate electrode on the substrate falls within an orthographic projection of the light shielding portion on the substrate.

In an embodiment, the array substrate further comprises a third via hole penetrating the buffer layer and the interlayer dielectric layer and corresponding to the source electrode. The transparent electrode is electrically connected to the source electrode through the third via hole.

The present disclosure further provides a method for manufacturing an array substrate, which comprises:

providing a substrate;

forming a first metal layer on the substrate;

patterning the first metal layer by a yellow light process to form a source electrode, a drain electrode, and a light shielding portion;

forming a buffer layer on the first metal layer, wherein the buffer layer covers the substrate, the source electrode, the drain electrode, and the light shielding portion;

patterning the buffer layer to form a first via hole corresponding to the source electrode and a second via hole corresponding to the drain electrode;

forming an active layer on the buffer layer; and

patterning the active layer to form a semiconductor layer, wherein the semiconductor layer is electrically connected to the source electrode through the first via hole, and is electrically connected to the drain electrode through the second via hole.

In an embodiment, the method for manufacturing the array substrate, after the patterning the active layer to form the semiconductor layer, further comprising:

sequentially forming an insulating layer and a second metal layer on the semiconductor layer;

patterning the insulating layer and the second metal layer, so that the insulating layer forms a gate insulating layer, and the second metal layer at least forms a gate electrode;

forming an interlayer dielectric layer on the second metal layer;

forming a transparent conductive layer on the interlayer dielectric layer; and

patterning the transparent conductive layer to form a transparent electrode.

In an embodiment, the method for manufacturing the array substrate, before the forming the transparent conductive layer on the interlayer dielectric layer, further comprises:

patterning the interlayer dielectric layer and the buffer layer to form a third via hole penetrating the buffer layer and the interlayer dielectric layer, wherein the transparent electrode is electrically connected to the source electrode through the third via hole.

The present disclosure further provides a display panel comprising a counter substrate, a liquid crystal layer, and an array substrate. The array substrate and the counter substrate are disposed oppositely and spaced apart. The liquid crystal layer is disposed between the array substrate and the counter substrate. The array substrate comprises:

a substrate;

a first metal layer disposed on the substrate and comprising a source electrode, a drain electrode, and a light shielding portion;

a buffer layer covering the first metal layer and provided with a first via hole penetrating the buffer layer and corresponding to the source electrode and a second via hole penetrating the buffer layer and corresponding to the drain electrode; and

a semiconductor layer disposed on the buffer layer, electrically connected to the source electrode through the first via hole, and electrically connected to the drain electrode through the second via hole.

In an embodiment, the source electrode and the drain electrode are disposed on and spaced apart from opposite sides of the light shielding portion.

In an embodiment, the source electrode and the drain electrode are disposed on opposite sides of the light shielding portion. One side of the light shielding portion is connected to the source electrode, and the other side of the light shielding portion is spaced apart from the drain electrode. Alternatively, one side of the light shielding portion is connected to the drain electrode, and the other side of the light shielding portion is spaced apart from the source electrode.

In an embodiment, the array substrate further comprises:

a gate insulating layer disposed on the semiconductor layer;

a second metal layer disposed on the gate insulating layer and comprising a gate electrode;

an interlayer dielectric layer covering the buffer layer, the semiconductor layer, the gate insulating layer, and the gate electrode; and

a transparent electrode disposed on the interlayer dielectric layer and electrically connected to the source electrode.

In an embodiment, an orthographic projection of the gate electrode on the substrate falls within an orthographic projection of the light shielding portion on the substrate.

In an embodiment, the array substrate further comprises a third via hole penetrating the buffer layer and the interlayer dielectric layer and corresponding to the source electrode. The transparent electrode is electrically connected to the source electrode through the third via hole.

In an embodiment, the first metal layer is made of Cu, Al, Mo, Ti, Nb, Ni, or an alloy thereof.

In an embodiment, the array substrate further comprises a plurality of signal traces, the signal traces comprise a plurality of data lines disposed on a same layer as the first metal layer.

In an embodiment, the data line is disposed on a side of the drain electrode away from the light shielding portion, and is electrically connected to the drain electrode.

In an embodiment, the semiconductor layer comprises a first doped portion and a second doped portion located at opposite ends of the semiconductor layer, the first doped portion is electrically connected to the source electrode through the first via hole, and the second doped portion is electrically connected to the drain electrode through the second via hole.

In an embodiment, the semiconductor layer is made of an oxide semiconductor.

In the array substrate, the method for manufacturing the same, and the display panel provided by the present disclosure, the source electrode, the drain electrode, and the light shielding portion are disposed on the substrate in a same layer. Therefore, the source electrode, the drain electrode, and the light shielding portion can be formed by a same yellow light process. The semiconductor layer is electrically connected to the source electrode through the first via hole penetrating the buffer layer, and is electrically connected to the drain electrode through the second via hole penetrating the buffer layer. In this way, a number of photomasks and a number of process steps are reduced, which is beneficial to reduce costs.

### BRIEF DESCRIPTION OF DRAWINGS

In order to more clearly illustrate technical solutions in embodiments or the prior art, a brief description of accompanying drawings used in the embodiments or the prior art will be given below. The accompanying drawings in the following description are merely some embodiments of the present disclosure. For those skilled in the art, other drawings may be obtained from these accompanying drawings without creative labor.

FIG. 1 is a schematic diagram of a cross-sectional structure of a first type of array substrate according to an embodiment of the present disclosure.

FIG. 2 is a schematic diagram of a cross-sectional structure of a second type of array substrate according to an embodiment of the present disclosure.

FIG. 3 is a schematic diagram of a cross-sectional structure of a third type of array substrate according to an embodiment of the present disclosure.

FIG. 4 is a flowchart of a method for manufacturing an array substrate according to an embodiment of the present disclosure.

FIGS. 5-10 are structural schematic flowcharts of the method for manufacturing the array substrate according to the embodiment of the present disclosure.

FIG. 11 is a schematic cross-sectional structure diagram of a display panel according to an embodiment of the present disclosure.

Reference numerals are described as follows:

100: array substrate, 200: counter substrate, 300: liquid crystal layer, 1: substrate, 2: first metal layer, 21: source electrode, 22: drain electrode, 23: light shielding portion, 24: first gap, 25: second gap, 3: buffer layer, 31: first via hole, 32: second via hole, 33: third via hole, 4: semiconductor layer, 41: active layer, 5: gate insulating layer, 51: insulating layer, 6: second metal layer, 61: gate electrode, 7: interlayer dielectric layer, 8: transparent electrode, 81: transparent conductive layer, 10: first photoresist layer, 10′: first photoresist pattern, 20: second photoresist layer, 20′: second photoresist pattern, 30: third photoresist layer, 30′: third photoresist pattern, 40: fourth photoresist layer, 40′: fourth photoresist pattern, 50: fifth photoresist layer, 50′: fifth photoresist pattern, 60: sixth photoresist layer, and 60′: sixth photoresist pattern.

### DETAILED DESCRIPTION

Technical solutions in embodiments of the present disclosure will be clearly and completely described below in conjunction with accompanying drawings in the embodiments of the present disclosure. It is apparent that the described embodiments are merely a part of the embodiments of the present disclosure and not all embodiments. All other embodiments obtained by those skilled in the art based on the embodiments of the present disclosure without creative labor are within claimed scope of the present disclosure. In addition, it should be understood that specific embodiments described herein are only used to illustrate and explain the present invention, and are not used to limit the present invention. In the present disclosure, unless otherwise stated, directional terms used herein specifically indicate directions of the accompanying drawings. For example, directional terms “upper” and “lower” generally refer to upper and lower positions of a device in actual use or working conditions, and directional terms “inside” and “outside” refer to positions relative to a profile of the device.

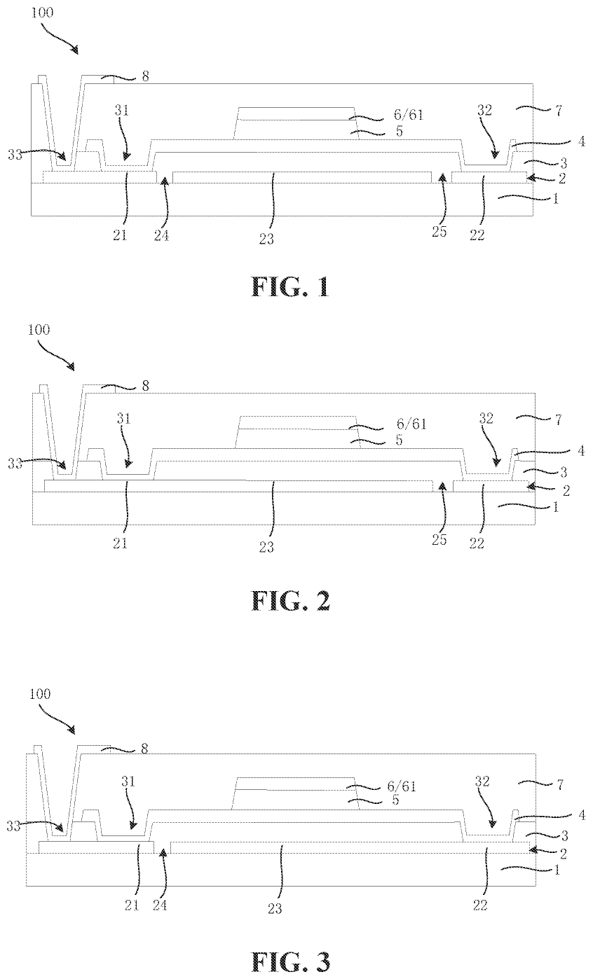

Please refer to FIG. 1, the present disclosure provides an array substrate 100. The array substrate 100 comprises a substrate 1, a first metal layer 2, a buffer layer 3, and a semiconductor layer 4. The first metal layer 2 is disposed on the substrate 1. The first metal layer 2 comprises a source electrode 21, a drain electrode 22, and a light shielding portion 23. The buffer layer 3 covers the substrate 1, the source electrode 21, the drain electrode 22, and the light shielding portion 23. The semiconductor layer 4 is disposed on the buffer layer 3.

The buffer layer 3 is provided with a first via hole 31 penetrating the buffer layer 3 and corresponding to the source electrode 21 and a second via hole 32 penetrating the buffer layer 3 and corresponding to the drain electrode 22. The semiconductor layer 4 is electrically connected to the source electrode 21 through the first via hole 31, and is electrically connected to the drain electrode 22 through the second via hole 32.

In the present disclosure, the source electrode 21, the drain electrode 22, and the light shielding portion 23 are all disposed on the substrate 1. That is, the source electrode 21, the drain electrode 22, and the light shielding portion 23 are located in a same layer. Compared with the source electrode 21 and the drain electrode 22 located in different layers in the prior art, a layer structure of the array substrate 100 of the present disclosure is optimized. An overall thickness of the layers is reduced, which is beneficial to a thin design of a panel. Furthermore, the source electrode 21, the drain electrode 22, and the light shielding portion 23 can be made of a same metal material, so that the source electrode 21, the drain electrode 22, and the light shielding portion 23 can be formed by using a same photomask, which is beneficial to reduce a number of photomasks and a number of process steps, thereby effectively reducing production costs.

Specifically, the source electrode 21, the drain electrode 22, and the light shielding portion 23 are made of a same material. The first metal layer 2 is made of Cu, Al, Mo, Ti, Nb, Ni, or an alloy thereof. The first metal layer 2 may be a single-layer metal layer or a multi-layer metal layer. For example, when the first metal layer 2 is a double-layer metal layer, its bottom layer is made of Mo, Ti, Nb, Ni, or an alloy thereof, and its upper layer is Cu or Al.

Specifically, the array substrate 100 further comprises a gate insulating layer 5, a second metal layer 6, an interlayer dielectric layer 7, and a transparent electrode 8. The gate insulating layer 5 is disposed on the semiconductor layer 4. The second metal layer 6 is disposed on the gate insulating layer 5. The second metal layer 6 comprises a gate electrode 61. The interlayer dielectric layer 7 covers the buffer layer 3, the semiconductor layer 4, the gate insulating layer 5, and the gate electrode 61. The transparent electrode 8 is disposed on the interlayer dielectric layer 7. The transparent electrode 8 is electrically connected to the source electrode 21.

Specifically, the substrate 1 may be a glass substrate or a flexible substrate. The buffer layer 3 may be made of silicon oxide, silicon nitride, or a mixed material thereof to have a buffering effect. The semiconductor layer 4 is made of an oxide semiconductor such as indium gallium zinc oxide (IGZO). The gate insulating layer 5 may be made of a silicon dioxide material, a silicide nitride material, a multi-layer material structure of silicon oxide and silicon nitride, or a combination thereof. The second metal layer 6 comprises the gate electrode 61. The gate electrode 61 may be made of Al, Mo, Cu, Cr, Au, Ni, Nd, or a combination thereof. The interlayer dielectric layer 7 may be made of silicon oxide, silicon nitride, or a combination thereof. The transparent electrode 8 may be made of a transparent conductive material such as indium tin oxide.

The present disclosure does not limit relative positions of the light shielding portion 23, the source electrode 21, and the drain electrode 22. It is only necessary to ensure that the light shielding portion 23, the source electrode 21, and the drain electrode 22 are disposed in a same layer. For example, the source electrode 21 may be disposed between the light shielding portion 23 and the drain electrode 22. Alternatively, the drain electrode 22 may be disposed between the light shielding portion 23 and the source electrode 21. Alternatively, the light shielding portion 23 may be disposed between the source electrode 21 and the drain electrode 22. Preferably, because the semiconductor layer 4 and the gate electrode 61 are generally disposed in a middle of a thin film transistor device, in order to reasonably dispose and optimize a layout of layers of the thin film transistor device, the light shielding portion 23 is disposed between the source electrode 21 and the drain electrode 22. That is, the source electrode 21 and the drain electrode 22 are respectively disposed on opposite sides of the light shielding portion 23.

In an embodiment, please refer to FIG. 1, the source electrode 21 and the drain electrode 22 are disposed on and spaced apart from the opposite sides of the light shielding portion 23. That is, there is a first gap 24 between the source electrode 21 and the light shielding portion 23. There is a second gap 25 between the drain electrode and the light shielding portion. The source electrode 21 and the light shielding portion 23 are not connected. The drain 22 and the light shielding portion 23 are not connected.

In an embodiment, in order to prevent external light from entering the semiconductor layer 4 through a gap between the light shielding portion 23 and the source electrode 21 or a gap between the light shielding portion 23 and the drain electrode 22 and causing device degradation, without affecting normal operation of the source electrode 21 and the drain electrode 22, the light shielding portion 23 may be connected to the source electrode 21 or the drain electrode 22. There is the second gap 25 between the drain electrode and the light shielding portion. Specifically, as shown in FIG. 2, differences between FIG. 2 and FIG. 1 are that the source electrode 21 and the drain electrode 22 are respectively disposed on the opposite sides of the light shielding portion 23, one side of the light shielding portion 23 is connected to the source electrode 21, and the other side of the light shielding portion 23 is spaced apart from the drain electrode 22. There is the second gap 25 between the other side of the light shielding portion 23 and the drain electrode. That is, the source electrode 21 and the light shielding portion 23 play a role of light shielding together. Alternatively, as shown in FIG. 3, differences between FIG. 3 and FIG. 1 are that the source electrode 21 and the drain electrode 22 are respectively disposed on the opposite sides of the light shielding portion 23, one side of the light shielding portion 23 is connected to the drain electrode 22, and the other side of the light shielding portion 23 is spaced apart from the source electrode 21. There is the second gap 24 between the other side of the light shielding portion 23 and the source electrode 21. That is, the drain electrode 22 and the light shielding portion 23 play the role of light shielding together.

It should be noted that, in order to prevent light from entering the semiconductor layer 4 through the first gap 24 or the second gap 25, a size of the first gap 24 or the second gap 25 should not be too large.

Specifically, the semiconductor layer 4 comprises a doped portion located at its opposite ends and a non-doped portion located at its middle. The doped portion may be made of a semiconductor material doped with a dopant material. The non-doped portion may be made of a semiconductor material that is not doped with a dopant material. The doped portion comprises a first doped portion and a second doped portion. The non-doped portion is located between the first doped portion and the second doped portion. The first doped portion corresponds to the source electrode 21, and the second doped portion corresponds to the drain electrode 22. That is, the doped portion not covered by the gate electrode 61 is made conductive, and the non-doped portion covered by the gate electrode 61 is not made conductive. The light shielding portion 23 is configured to block external light to prevent light from entering the semiconductor layer 4 and causing deterioration of device performance. Furthermore, in order to prevent light from entering the non-doped portion, in an embodiment of the present disclosure, an orthographic projection of the gate electrode 61 on the substrate 1 falls within an orthographic projection of the light shielding portion 23 on the substrate 1. That is, an orthographic projection of the non-doped portion on the substrate 1 falls within the orthographic projection of the light shading portion 23 on the substrate 1.

Specifically, the first doped portion is electrically connected to the source electrode 21 through the first via hole 31, and the second doped portion is electrically connected to the drain electrode 22 through the second via hole 32.

The array substrate 100 further comprises a third via hole 33. The third via hole 33 penetrates the interlayer dielectric layer 7 and the buffer layer 3. The third via hole 33 corresponds to the source electrode 21. The transparent electrode 8 is electrically connected to the source electrode 21 through the third via hole 33.

It can be understood that, compared with the prior art, the present disclosure omits a passivation layer covering the second metal layer 6 and the interlayer dielectric layer 7, which reduces a number of layers of the array substrate 100. As a result, the layer structure of the array substrate 100 is further optimized. The overall thickness of the layers is further reduced, which is beneficial to the thin design of the panel and reduces the production costs.

Specifically, the array substrate 100 may be a vertical alignment (VA)/in-plane switching (IPS)/fringe field switching (FFS)/organic light-emitting diode (OLED)/mini light-emitting diode (mini-LED)/micro light-emitting diode (micro-LED) array substrate.

The array substrate 100 further comprises a driving circuit for driving the thin film transistor device. The driving circuit comprises a plurality of signal traces. The signal traces comprise a plurality of data lines and a plurality of scan lines. The data lines are disposed on a same layer as the first metal layer 2. Specifically, the data lines, the source electrode 21, the drain electrode 22, and the light shielding portion 23 are located in a same layer. One of the data lines is disposed on a side of the drain electrode 22 away from the light shielding portion 23, and is electrically connected to the drain electrode 22. The scan lines are disposed on a same layer as the second metal layer 6. Specifically, the scan lines and the gate electrode 61 are located in a same layer. One of the scan lines is electrically connected to the gate electrode 61.

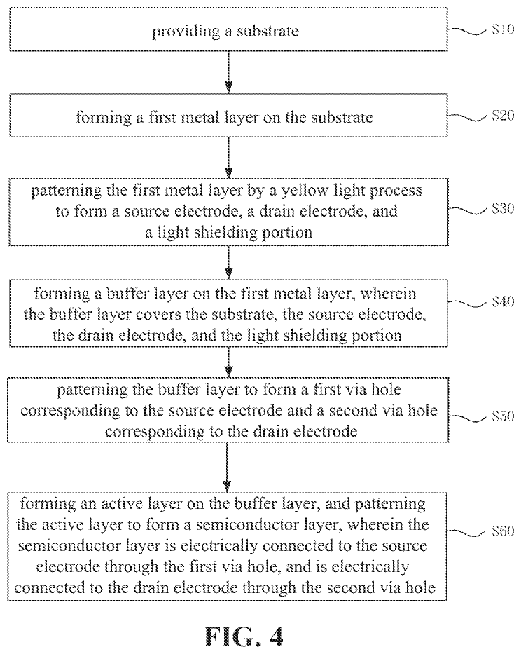

Please refer to FIG. 4, the present disclosure further provides a method for manufacturing an array substrate 100, comprising:

S10: providing a substrate 1;

S20: forming a first metal layer 2 on the substrate 1; and

S30: patterning the first metal layer 2 by a yellow light process to form a source electrode 21, a drain electrode 22, and a light shielding portion 23.

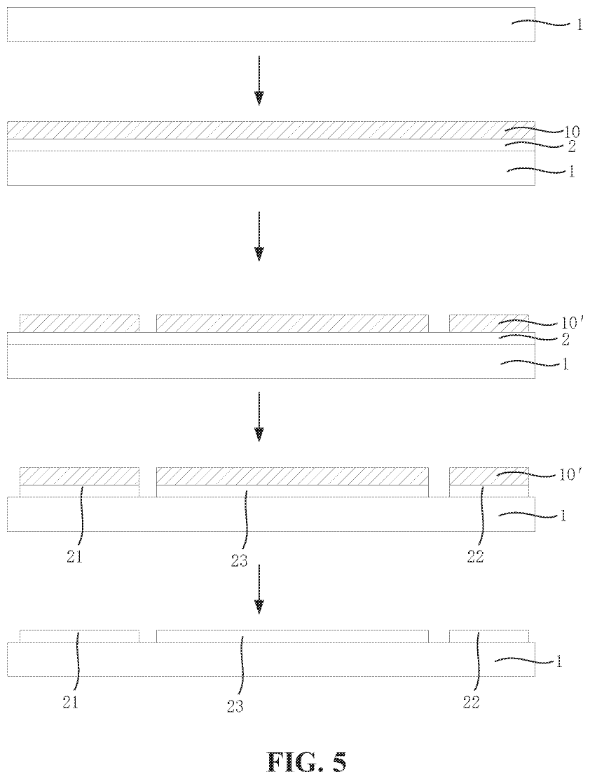

Specifically, as shown in FIG. 5, first, the first metal layer 2 and a first photoresist layer 10 are sequentially deposited on the substrate 1. Then, the first photoresist layer 10 is exposed and developed through a first mask (Mask 1) to form a first photoresist pattern 10′. Then, the first metal layer 2 is etched using the first photoresist pattern 10′ as a mask to form the source electrode 21, the drain electrode 22, and the light shielding portion 23. Finally, the first photoresist pattern 10′ is removed.

Specifically, the substrate 1 may be a glass substrate or a flexible substrate. The first metal layer 2 is made of Cu, Al, Mo, Ti, Nb, Ni, or an alloy thereof.

Furthermore, after the step S30, the method further comprises the following steps.

S40: forming a buffer layer 3 on the first metal layer 2, wherein the buffer layer 3 covers the substrate 1, the source electrode 21, the drain electrode 22, and the light shielding portion 23.

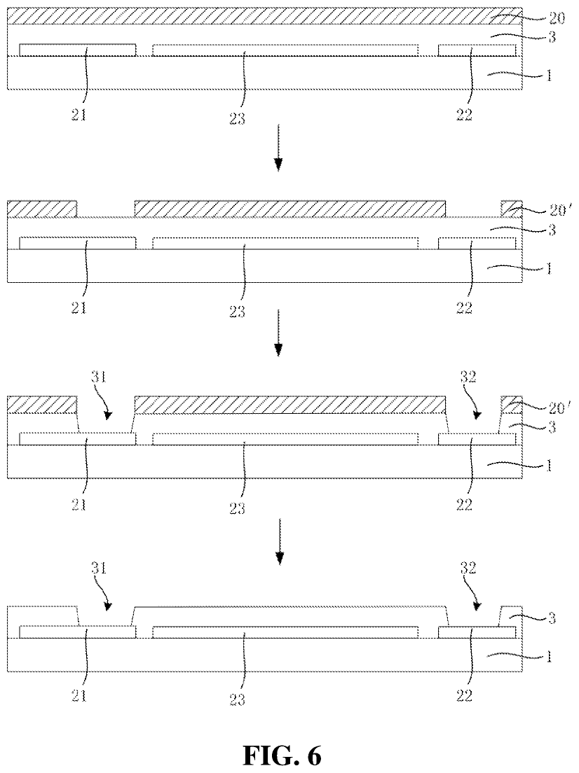

Specifically, as shown in FIG. 6, the buffer layer 3 is deposited on an entire surface of the substrate 1 of FIG. 5. The buffer layer 3 covers the substrate 1, the source electrode 21, the drain electrode 22, and the light shielding portion 23. Specifically, the buffer layer 3 may be made of silicon oxide, silicon nitride, or a mixed material thereof.

S50: patterning the buffer layer 3 to form a first via hole 31 corresponding to the source electrode 21 and a second via hole 32 corresponding to the drain electrode 22.

Specifically, please refer to FIG. 6, a second photoresist layer 20 is first deposited on the buffer layer 3. Then, the second photoresist layer 20 is exposed and developed through a second mask (Mask 2) to form a second photoresist pattern 20′. Then, the buffer layer 3 is etched using the second photoresist pattern 20′ as a mask to form the first via hole 31 and the second via hole 32. Finally, the third photoresist pattern 20′ is removed.

S60: forming an active layer 41 on the buffer layer 3, and patterning the active layer 41 to form a semiconductor layer 4, wherein the semiconductor layer 4 is electrically connected to the source electrode 21 through the first via hole 31, and is electrically connected to the drain electrode 22 through the second via hole 32.

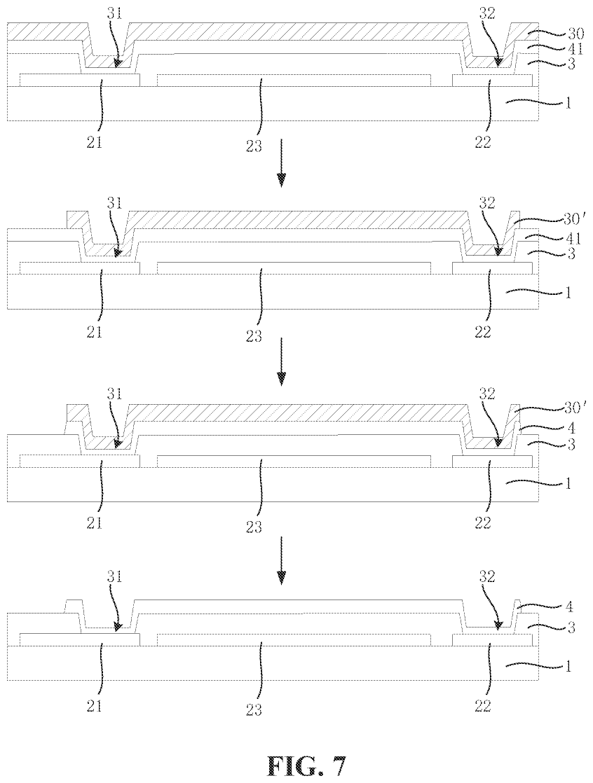

Specifically, as shown in FIG. 7, first, the active layer 41 and a third photoresist layer 30 are sequentially deposited on the buffer layer 3 of FIG. 6. The active layer 41 covers the buffer layer 3, the first via hole 31, and the second via hole 32. Then, the third photoresist layer 30 is exposed and developed through a third mask (Mask 3) to form a third photoresist pattern 30′. Then, the active layer 41 is etched using the third photoresist pattern 30′ as a mask. Then, the third photoresist pattern 30′ is removed. Finally, the active layer 41 is doped to form the semiconductor layer 4. The semiconductor layer 4 comprises a first doped portion and a second doped portion located at its opposite ends, and further comprises a non-doped portion located between the first doped portion and the second doped portion. The first doped portion is electrically connected to the source electrode 21 through the first via hole 31, and the second doped portion is electrically connected to the drain electrode 22 through the second via hole 32.

Specifically, the semiconductor layer 4 may be made of IGZO.

S70: sequentially forming an insulating layer 51 and a second metal layer 6 on the semiconductor layer 4.

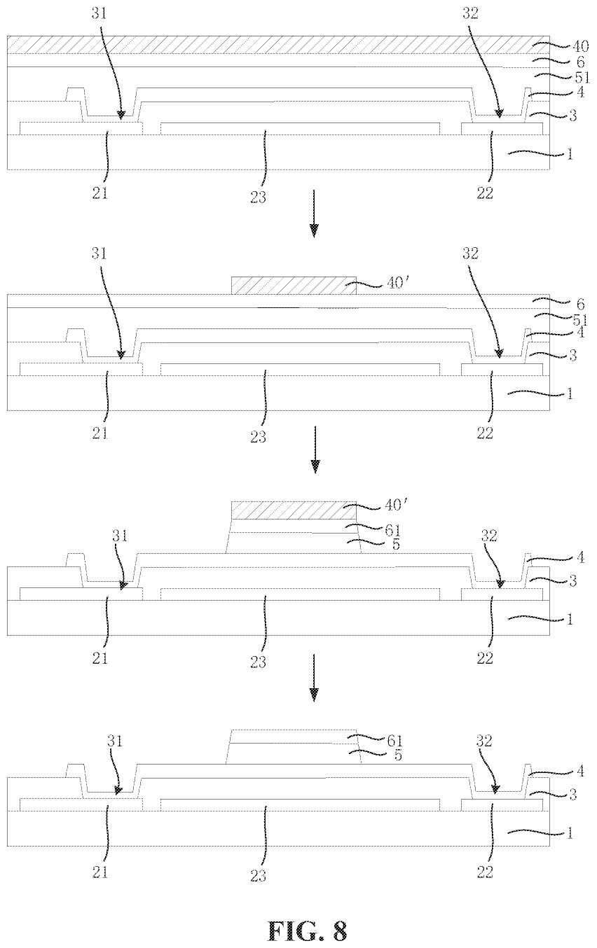

Specifically, as shown in FIG. 8, the insulating layer 51 and the second metal layer 6 are sequentially deposited on the buffer layer 3 of FIG. 7, wherein the insulating layer 51 covers the buffer layer 3 and the semiconductor layer 4.

S80: patterning the insulating layer 51 and the second metal layer 6, so that the insulating layer 51 forms a gate insulating layer 5, and the second metal layer 6 at least forms a gate electrode 61.

Specifically, please refer to FIG. 8, a fourth photoresist layer 40 is first deposited on the second metal layer 6. Then the fourth photoresist layer 40 is exposed and developed through a fourth mask (Mask 4) to form a fourth photoresist pattern 40′. Then, the insulating layer 51 and the second metal layer 6 are etched using the fourth photoresist pattern 40′ as a mask to form the gate insulating layer 5 and the gate electrode 61, respectively. Finally, the fourth photoresist pattern 40′ is removed.

Specifically, the gate insulating layer 5 may be made of a silicon dioxide material, a silicide nitride material, a multi-layer material structure of silicon oxide and silicon nitride, or a combination thereof. The gate electrode 61 may be made of Al, Mo, Cu, Cr, Au, Ni, Nd, or a combination thereof.

S90: forming an interlayer dielectric layer 7 on the second metal layer 6.

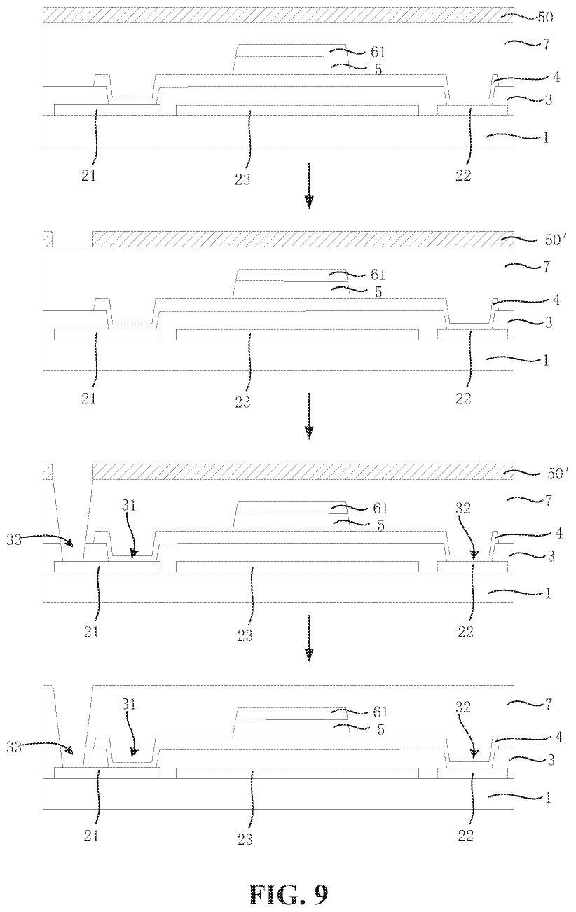

Specifically, as shown in FIG. 9, the interlayer dielectric layer 7 is deposited on the second metal layer 6 of FIG. 8. The interlayer dielectric layer 7 covers the buffer layer 3, the semiconductor layer 4, the gate insulating layer 5, and the gate electrode 61. The interlayer dielectric layer 7 may be made of silicon oxide, silicon nitride, or a combination thereof.

S100: patterning the interlayer dielectric layer 7 and the buffer layer 3 to form a third via hole 33 penetrating the buffer layer 3 and the interlayer dielectric layer 73.

Specifically, please refer to FIG. 9, the fifth photoresist layer 50 is first deposited on the interlayer dielectric layer 7. Then, the fifth photoresist layer 50 is exposed and developed through a fifth photomask (Mask 5) to form a fifth photoresist pattern 50′. Then, the interlayer dielectric layer 7 and the buffer layer 3 are etched using the fifth photoresist pattern 50′ as a mask to form the third via hole 33. Finally, the fifth photoresist pattern 50′ is removed. The third via hole 33 penetrates the buffer layer and the interlayer dielectric layer 7 and corresponds to the source electrode 21.

The interlayer dielectric layer 7 may be made of silicon oxide, silicon nitride, or a combination thereof.

S110: forming a transparent conductive layer 81 on the interlayer dielectric layer 7.

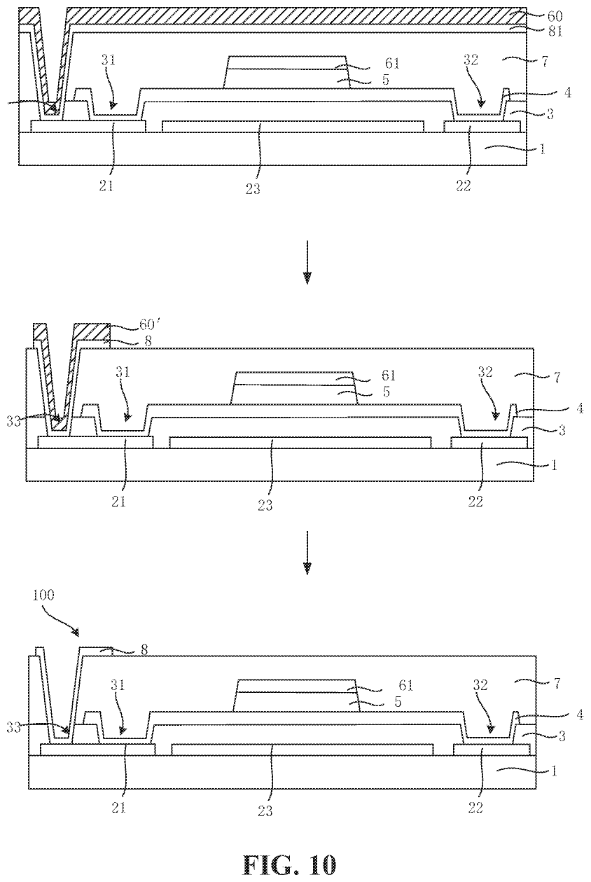

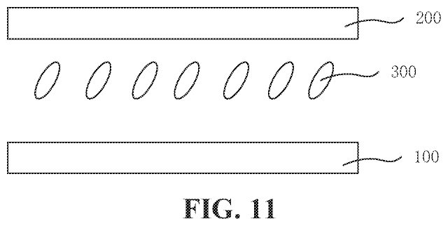

Specifically, as shown in FIG. 10, the transparent conductive layer 81 is deposited on an entire surface of the interlayer dielectric layer 7. The transparent conductive layer 81 covers the interlayer dielectric layer 7 and the third via hole 33.

S120: patterning the transparent conductive layer 81 to form a transparent electrode 8.

Specifically, please refer to FIG. 10, first, the transparent conductive layer 81 and a sixth photoresist layer 60 are deposited on the transparent conductive layer 81. Then, the sixth photoresist layer 60 is exposed and developed through a sixth mask (Mask 6) to form a sixth photoresist pattern 60′. Then, the transparent conductive layer 81 is etched using the sixth photoresist pattern 60′ as a mask to form the transparent electrode 8. Finally, the sixth photoresist pattern 60′ is removed. The transparent electrode 8 is electrically connected to the source electrode 21 through the third via hole 33.

Specifically, the transparent electrode 8 may be made of a transparent conductive material such as indium tin oxide.

Accordingly, the array substrate 100 provided by the present disclosure is made through the above steps.

It can be understood that the method for manufacturing the array substrate 100 provided by the present disclosure only requires six yellow light processes. The six yellow light processes are specifically used to prepare the source electrode 21, the drain electrode 22, and the light shielding portion 23; the first via hole 31 and the second via hole 32; the semiconductor layer 4; the gate insulating layer 5 and the gate electrode 61; the third via hole 33; and the transparent electrode 8, respectively. Compared with a current method for manufacturing an array substrate, the present disclosure saves at least two yellow light processes, thereby reducing a number of photomasks and a number of process steps, which is beneficial to reduce costs.

Please refer to FIG. 11, the present disclosure further provides a display panel. The display panel comprises a counter substrate 200, a liquid crystal layer 300, and the array substrate 100 described in the above embodiments. The array substrate 100 and the counter substrate 200 are disposed oppositely and spaced apart. The liquid crystal layer 300 is disposed between the array substrate 100 and the counter substrate.

In the array substrate, the method for manufacturing the same, and the display panel provided by the present disclosure, the source electrode, the drain electrode, and the light shielding portion are disposed on the substrate in a same layer. Therefore, the source electrode, the drain electrode, and the light shielding portion can be formed by a same yellow light process. The semiconductor layer is electrically connected to the source electrode through the first via hole penetrating the buffer layer, and is electrically connected to the drain electrode through the second via hole penetrating the buffer layer. In this way, a number of photomasks and a number of process steps are reduced, which is beneficial to reduce costs.

In the above, the present application has been described in the above preferred embodiments, but the preferred embodiments are not intended to limit the scope of the present application, and those skilled in the art may make various changes and modifications without departing from the scope of the present application. The scope of the present application is determined by claims.

1. An array substrate, comprising:
a substrate;
a first metal layer disposed on the substrate and comprising a source electrode, a drain electrode, and a light shielding portion;
a buffer layer covering the first metal layer and provided with a first via hole penetrating the buffer layer and corresponding to the source electrode and a second via hole penetrating the buffer layer and corresponding to the drain electrode; and
a semiconductor layer disposed on the buffer layer, electrically connected to the source electrode through the first via hole, and electrically connected to the drain electrode through the second via hole.

2. The array substrate according to claim 1, wherein the source electrode and the drain electrode are disposed on and spaced apart from opposite sides of the light shielding portion.

3. The array substrate according to claim 1, wherein the source electrode and the drain electrode are disposed on opposite sides of the light shielding portion, and
one side of the light shielding portion is connected to the source electrode, and the other side of the light shielding portion is spaced apart from the drain electrode; or
one side of the light shielding portion is connected to the drain electrode, and the other side of the light shielding portion is spaced apart from the source electrode.

4. The array substrate according to claim 1, further comprising:
a gate insulating layer disposed on the semiconductor layer;
a second metal layer disposed on the gate insulating layer and comprising a gate electrode;
an interlayer dielectric layer covering the buffer layer, the semiconductor layer, the gate insulating layer, and the gate electrode; and
a transparent electrode disposed on the interlayer dielectric layer and electrically connected to the source electrode.

5. The array substrate according to claim 4, wherein an orthographic projection of the gate electrode on the substrate falls within an orthographic projection of the light shielding portion on the substrate.

6. The array substrate according to claim 4, further comprising a third via hole penetrating the buffer layer and the interlayer dielectric layer and corresponding to the source electrode, wherein the transparent electrode is electrically connected to the source electrode through the third via hole.

7. A method for manufacturing an array substrate, comprising:
providing a substrate;
forming a first metal layer on the substrate;
patterning the first metal layer by a yellow light process to form a source electrode, a drain electrode, and a light shielding portion;
forming a buffer layer on the first metal layer, wherein the buffer layer covers the substrate, the source electrode, the drain electrode, and the light shielding portion;
patterning the buffer layer to form a first via hole corresponding to the source electrode and a second via hole corresponding to the drain electrode;
forming an active layer on the buffer layer; and
patterning the active layer to form a semiconductor layer, wherein the semiconductor layer is electrically connected to the source electrode through the first via hole, and is electrically connected to the drain electrode through the second via hole.

8. The method for manufacturing the array substrate according to claim 7, after the patterning the active layer to form the semiconductor layer, further comprising:
sequentially forming an insulating layer and a second metal layer on the semiconductor layer;
patterning the insulating layer and the second metal layer, so that the insulating layer forms a gate insulating layer, and the second metal layer at least forms a gate electrode;
forming an interlayer dielectric layer on the second metal layer;
forming a transparent conductive layer on the interlayer dielectric layer; and
patterning the transparent conductive layer to form a transparent electrode.

9. The method for manufacturing the array substrate according to claim 8, before the forming the transparent conductive layer on the interlayer dielectric layer, further comprising:
patterning the interlayer dielectric layer and the buffer layer to form a third via hole penetrating the buffer layer and the interlayer dielectric layer, wherein the transparent electrode is electrically connected to the source electrode through the third via hole.

10. A display panel, comprising a counter substrate, a liquid crystal layer, and an array substrate, wherein the array substrate and the counter substrate are disposed oppositely and spaced apart, the liquid crystal layer is disposed between the array substrate and the counter substrate, and the array substrate comprises:
a substrate;
a first metal layer disposed on the substrate and comprising a source electrode, a drain electrode, and a light shielding portion;
a buffer layer covering the first metal layer and provided with a first via hole penetrating the buffer layer and corresponding to the source electrode and a second via hole penetrating the buffer layer and corresponding to the drain electrode; and
a semiconductor layer disposed on the buffer layer, electrically connected to the source electrode through the first via hole, and electrically connected to the drain electrode through the second via hole.

11. The display panel according to claim 10, wherein the source electrode and the drain electrode are disposed on and spaced apart from opposite sides of the light shielding portion.

12. The display panel according to claim 10, wherein the source electrode and the drain electrode are disposed on opposite sides of the light shielding portion, and
one side of the light shielding portion is connected to the source electrode, and the other side of the light shielding portion is spaced apart from the drain electrode; or
one side of the light shielding portion is connected to the drain electrode, and the other side of the light shielding portion is spaced apart from the source electrode.

13. The display panel according to claim 10, further comprising:
a gate insulating layer disposed on the semiconductor layer;
a second metal layer disposed on the gate insulating layer and comprising a gate electrode;
an interlayer dielectric layer covering the buffer layer, the semiconductor layer, the gate insulating layer, and the gate electrode; and
a transparent electrode disposed on the interlayer dielectric layer and electrically connected to the source electrode.

14. The display panel according to claim 13, wherein an orthographic projection of the gate electrode on the substrate falls within an orthographic projection of the light shielding portion on the substrate.

15. The display panel according to claim 13, further comprising a third via hole penetrating the buffer layer and the interlayer dielectric layer and corresponding to the source electrode, wherein the transparent electrode is electrically connected to the source electrode through the third via hole.

16. The display panel according to claim 10, wherein the first metal layer is made of Cu, Al, Mo, Ti, Nb, Ni, or an alloy thereof.

17. The display panel according to claim 10, wherein the array substrate further comprises a data line disposed on a same layer as the first metal layer.

18. The display panel according to claim 17, wherein the data line is disposed on a side of the drain electrode away from the light shielding portion, and is electrically connected to the drain electrode.

19. The display panel according to claim 10, wherein the semiconductor layer comprises a first doped portion and a second doped portion located at opposite ends of the semiconductor layer, the first doped portion is electrically connected to the source electrode through the first via hole, and the second doped portion is electrically connected to the drain electrode through the second via hole.

20. The display panel according to claim 10, wherein the semiconductor layer is made of an oxide semiconductor.
